(19) United States
(12) Patent Application Publication
(10) Pub. No.: US 2015/0009620 A1
(43) Pub. Date: Jan. 8, 2015

(54) ELECTRONIC APPARATUS

(71) Applicant: FUJITSU LIMITED, Kawasaki-shi (JP)

(72) Inventors: Yoshimi Kadotani, Kawasaki (JP); Misao Umematsu, Kawasaki (JP); Tsuyoshi So, Kawasaki (JP); Keita Hirai, Kawasaki (JP)

(21) Appl. No.: 14/311,559

(22) Filed: Jun. 23, 2014

(30) Foreign Application Priority Data
Jul. 2, 2013 (JP) 2013-139303

(51) Int. Cl. H05K 7/20

(52) U.S. Cl. CPC H05K 7/20818
USPC 361/679.47

(57) ABSTRACT

An electronic apparatus includes: an electronic device including a housing that accommodates a heat producing part, a heat transfer member configured to be exposed to an outer surface of the housing, and a heat pipe accommodated in the housing and configured to connect the heat producing part and the heat transfer member; and a cooling member, in contact with the heat transfer member, that is disposed on an outside of the housing, the cooling member in which a coolant circulating to and from an external coolant supply part.

### CROSS-REFERENCE TO RELATED APPLICATION

This application is based upon and claims the benefit of priority of the prior Japanese Patent Application No. 2013-139303, filed on Jul. 2, 2013, the entire contents of which are incorporated herein by reference.

### FIELD

The embodiment discussed herein is related to an electronic apparatus.

### BACKGROUND

An example of an electronic apparatus including an electronic device and a cooling mechanism which cools a heating part provided inside the electronic apparatus is as follows (for example, refer to Japanese Laid-open Patent Publication No. 2007-250752).

That is, the electronic apparatus includes an electronic device and a rack where the electronic device is mounted. The electronic device includes a housing that accommodates a heat producing part, a heat dissipating member, in contact with the heating part, that is accommodated in the housing, a heat transfer member provided on a side surface of the housing, and a liquid pipe for connecting the heat dissipating member and the heat transfer member.

In the heat dissipating member and the heat transfer member, a coolant is circulated via the liquid pipe. The rack includes a cooling member where the coolant is circulated from and to an external coolant supply part, and this cooling member is brought in contact with the heat transfer member.

According to the electronic apparatus, heat produced in the heat producing part is dissipated outside via the heat dissipating member, the heat transfer member, and the cooling member, thereby cooling the heat producing part.

However, in the above-described electronic apparatus, the heat dissipating member and the liquid tube where the coolant is circulated are provided inside the housing of the electronic device. Therefore, space saving inside the housing of the electronic device may be difficult.

Thus, it is desired to provide an electronic apparatus for space saving inside the housing of the electronic device.

### SUMMARY

According to an aspect of the invention, an electronic apparatus includes: an electronic device including a housing that accommodates a heat producing part, a heat transfer member configured to be exposed to an outer surface of the housing, and a heat pipe accommodated in the housing and configured to connect the heat producing part and the heat transfer member; and a cooling member, in contact with the heat transfer member, that is disposed on an outside of the housing, the cooling member in which a coolant circulating to and from an external coolant supply part.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of an electronic apparatus viewed from its rear surface side;

FIG. 2 depicts two surfaces of a single electronic device;

FIG. 3 is a longitudinal sectional view of a heat pipe;

FIG. 4 depicts four surfaces of the electronic device having a cooling unit mounted thereon;

FIG. 5 is a sectional view along a V-V line of FIG. 4;

FIG. 6 is an exploded plan view of the cooling unit;

FIG. 7 is a perspective view of the cooling unit;

FIG. 8 is a front view of a modification example of the cooling unit;

FIG. 9 depicts four surfaces of a modification example of the electronic device;

FIG. 10 depicts two surfaces of another modification example of the electronic device;

FIG. 11 is a sectional view along a XI-XI line of FIG. 10; and

FIG. 12 is a longitudinal sectional view of the state in which the electronic device depicted in FIG. 11 is mounted on a rack.

### DESCRIPTION OF EMBODIMENT

An embodiment of the technology disclosed herein is described below.

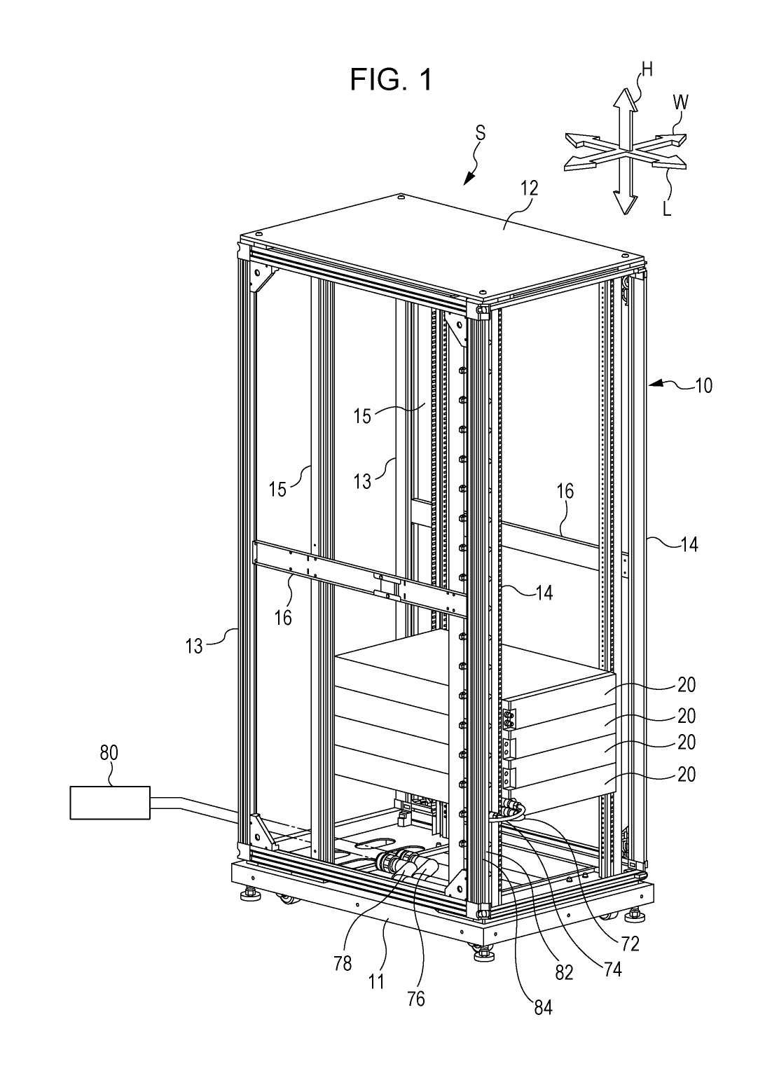

As depicted in FIG. 1, an electronic apparatus S according to the present embodiment includes a rack 10 and a plurality of electronic devices 20. In FIG. 1, an arrow L indicates a longitudinal direction of the electronic apparatus S, an arrow W indicates a lateral width direction of the electronic apparatus S, and an arrow H indicates a height direction of the electronic apparatus S. The longitudinal direction, the lateral width direction, and the height direction of the rack 10 and the electronic devices 20 are similar to those of the electronic apparatus S.

The rack 10 is a general-purpose 19-inch rack, by way of example. The rack 10 is formed in a rectangular parallelepiped elongated in a vertical direction, and has a lower frame 11, an upper plate 12, a plurality of poles 13 and 14, paired vertical frames 15, and paired lateral frames 16.

The plurality of electronic devices 20 are servers or the like, by way of example. The plurality of electronic devices 20 are mounted on the rack 10 as being stacked in the height direction of the rack 10. Each of the electronic devices 20 is fixed to the rack 10 as bridging between the paired vertical frames 15 and between paired poles 14 disposed on a rear surface side of the rack 10.

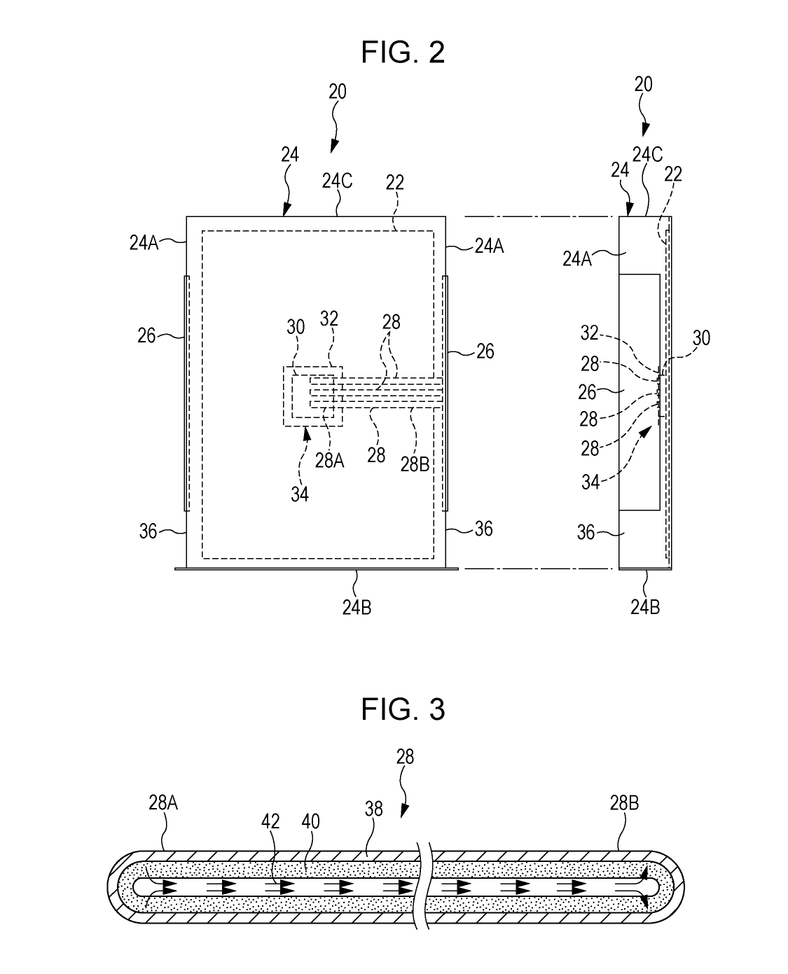

As depicted in FIG. 2, the electronic device 20 has a circuit board 22, a housing 24, paired heat transfer plates 26, and a plurality of heat pipes 28. The circuit board 22 is accommodated in the housing 24 formed in a flat box shape, and is disposed, with a height direction of the housing 24 taken as a plate thickness direction. On the circuit board 22, a heat producing body 30 is mounted. A heat dissipating plate 32 is fixed to a top surface of the heat producing body 30 as being superposed thereon. The heat producing body 30 is, for example, an arithmetic element of a central processing unit (CPU) or the like, and the heat producing body 30 and the heat dissipating plate 32 form a heat producing part 34.

The heat transfer plates 26 are an example of a heat transfer member. These heat transfer plates 26 are made of metal with high thermal conductivity such as copper, for example, and are provided along side surfaces 24A of outer surfaces (a top surface, a bottom surface, a front surface, a rear surface, and side surfaces) of the housing 24. Each of the heat transfer plates 26 is integrally provided with a sidewall part 36 forming one side surface 24A of the housing 24, thereby forming part of the sidewall part 36.

One surface of the heat transfer plate 26 is exposed to the side surface 24A, which is an outer surface of the sidewall part 36, and the other surface of the heat transfer plate 26 is exposed to an inner surface (an inner surface of the housing 24) of the sidewall part 36. The heat transfer plate 26 is formed so as to have a long length elongated in the longitudinal direction of the housing 24, and is provided from a front surface 24B side to a rear surface 24C side of the housing 24 on the side surface 24A.

The plurality of heat pipes 28 are accommodated in the housing 24. The plurality of heat pipes 28 each extend in the lateral width direction of the housing 24, and are disposed so as to be aligned along the longitudinal direction of the housing 24. One end of each of the heat pipes 28 is connected to the heat dissipating plate 32, and the other end of each of the heat pipes 28 is connected to one of the heat transfer plates 26. For the connection between each heat pipe 28 and the heat dissipating plate 32 and the connection between each heat pipe 28 and the heat transfer plate 26, welding is used, for example.

More specifically, as depicted in FIG. 3, each of the heat pipes 28 has a hollow pipe body 38, a porous body 40 (wick) provided on an inner surface of the pipe body 38, and hydraulic fluid 42 inside the pipe body 38. In the heat pipe 28, when the hydraulic fluid 42 evaporates at a heating part 28A to vapor, this vapor moves to a heat dissipating part 28B. When the vapor moving to the heat dissipating part 28B is condensed to be returned to the hydraulic fluid 42, the condensed hydraulic fluid 42 passes through the inside of the porous body 40 by capillarity to backflow to the heating part 28A. As depicted in FIG. 2, the heating part 28A of the heat pipe 28 is positioned near the heat producing part 34, and the heat dissipating part 28B of the heat pipe 28 is positioned near the heat transfer plate 26.

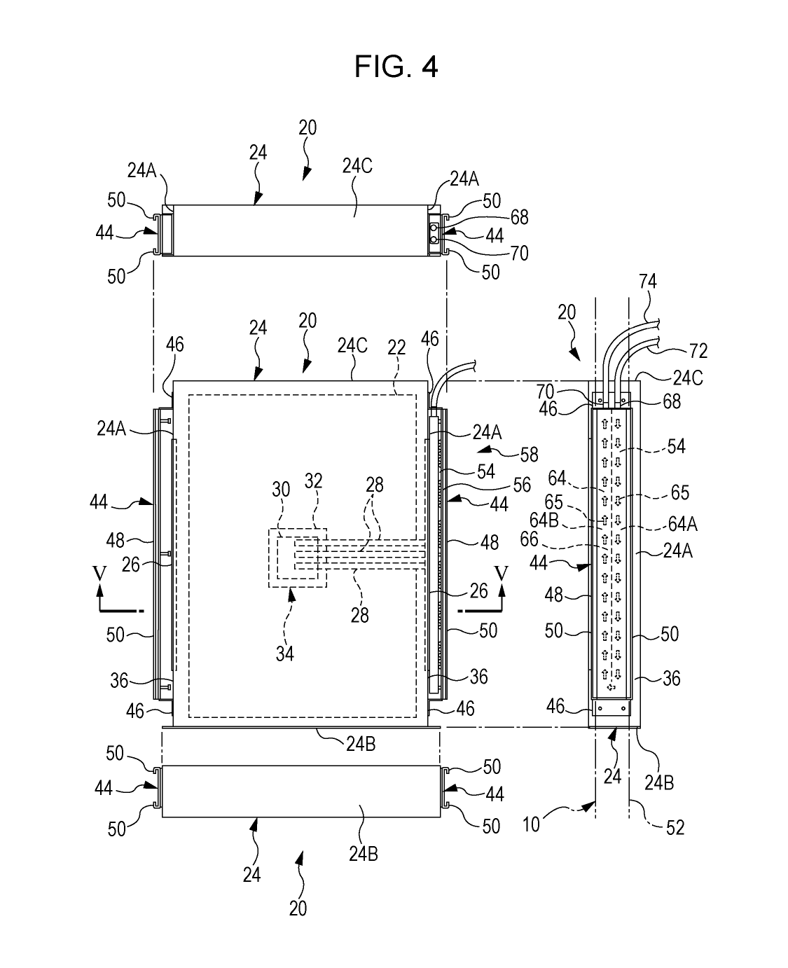

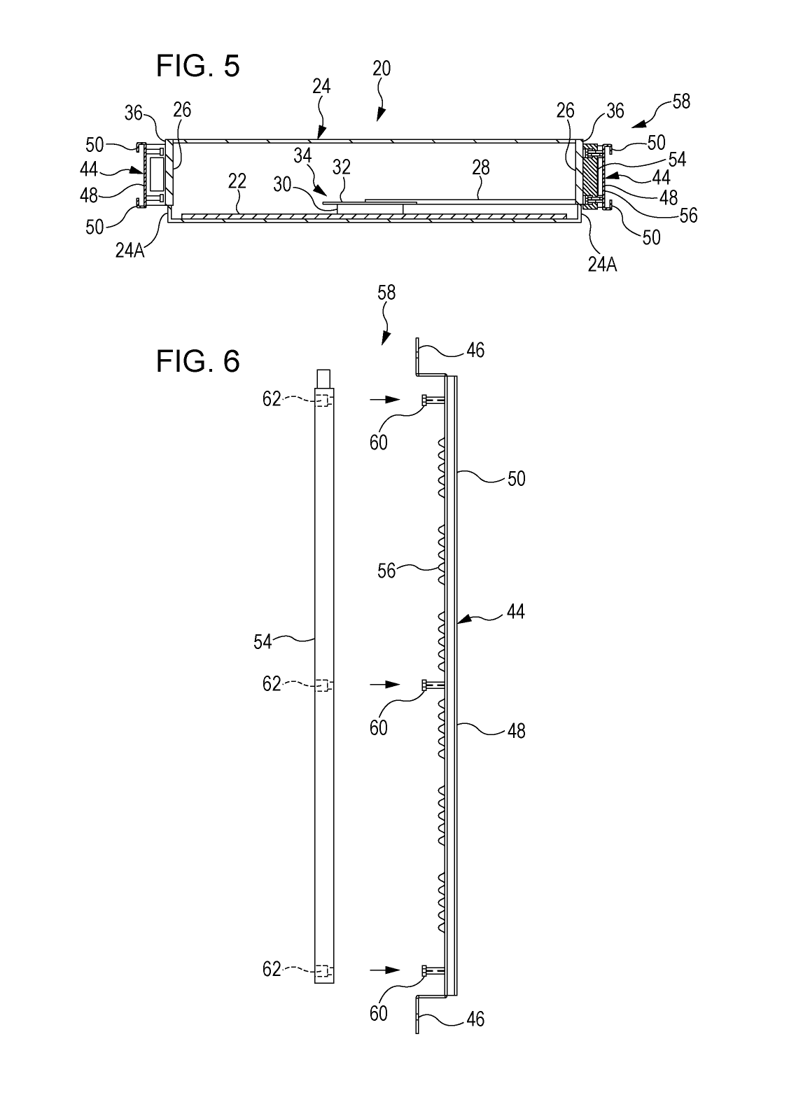

As depicted in FIG. 4 and FIG. 5, paired sliders 44 are provided on both side parts of the electronic device 20 according to the present embodiment. Each of the sliders 44 is formed so as to have a long length elongated in the longitudinal direction of the housing 24. The slider 44 is disposed, with the longitudinal direction of the housing 24 taken as a length direction, and is provided from the front surface 24B side to the rear surface 24C side of the side surface 24A of the housing 24. Paired flanges 46 are formed on both ends of the slider 44 in the length direction, and the slider 44 is fixed by the paired flanges 46 by being screwed to the side surface 24A of the housing 24.

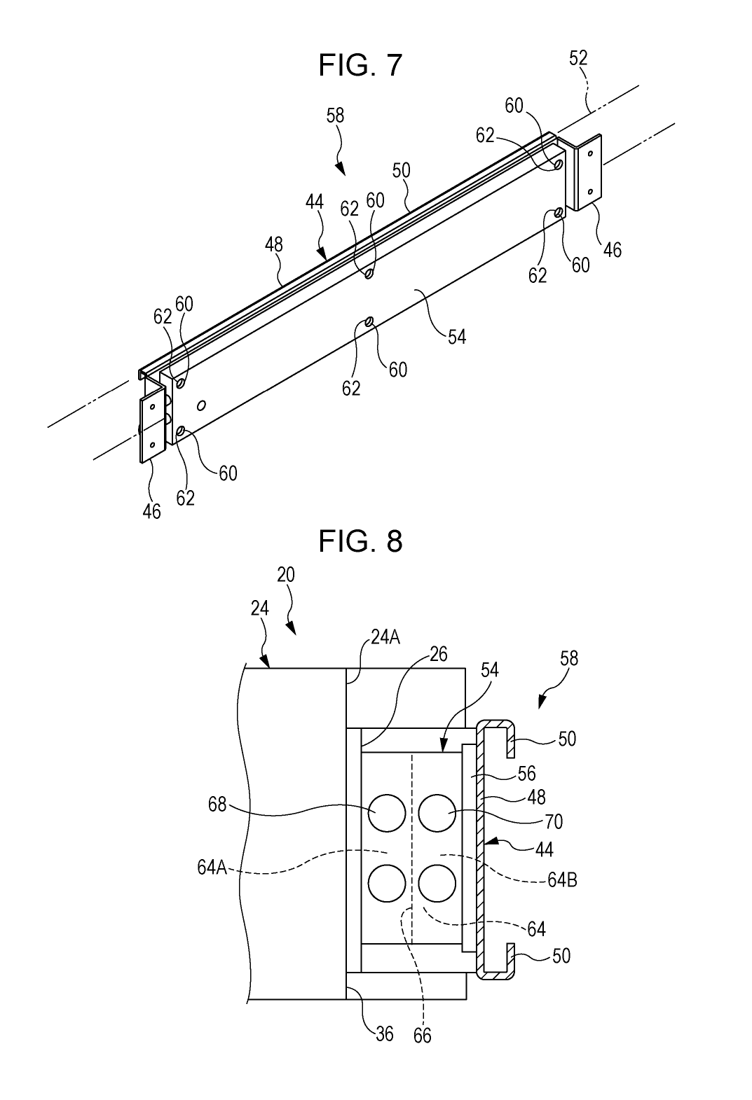

Between the paired flanges 46 of the slider 44, a body part 48 of the slider 44 is formed. Paired upper and lower guide rails 50 are formed at upper and lower ends of the body part 48. The paired guide rails 50 extend in the length direction of the slider 44 (in this case, the longitudinal direction of the housing 24). Each of the guide rails 50 is slidably supported by a guide part 52 provided to the rack 10 (also refer to FIG. 6 and FIG. 7). With the guide rail 50 supported by the guide part 52 in the above-described manner, the electronic device 20 is able to slide in the longitudinal direction of the rack 10.

With the slider 44 mounted on the side surface 24A of the housing 24, a gap is provided between the body part 48 of the slider 44 and the side surface 24A of the housing 24. In the present embodiment, by way of example, a cooling plate 54 and a spring 56 are provided between the body part 48 of one of the paired sliders 44 on both sides and the side surface 24A of the housing 24. The one slider 44, the cooling plate 54, and the spring 56 form a cooling unit 58.

The cooling plate 54 is an example of a cooling member, and is made of metal with high thermal conductivity such as copper, for example. The cooling plate 54 is formed in a long, flat plate shape and, as with the slider 44, is disposed with the longitudinal direction of the housing 24 as a length direction. Also, the cooling plate 54 is disposed outside the housing 24 so as to face the heat transfer plate 26.

As depicted in FIG. 6, pin-shaped supporting parts 60 are provided at both ends and the center of the body part 48 of the slider 44 in the length direction. In the cooling plate 54, hole parts 62 corresponding to the positions of these supporting parts 60 are formed. With the supporting parts 60 inserted in these hole parts 62, the both ends and the center of the cooling plate 54 in the length direction are fixed to the both ends and the center of the slider 44 in the length direction (the both ends and the center of the body part 48 in the length direction).

That is, the slider 44 described above has not only a function of slidably supporting the electronic device 20 to the rack 10 but also a function as a bracket for mounting the cooling plate 54 on the side surface 24A of the housing 24. Also, as described above, with the supporting parts 60 inserted in the hole parts 62, as depicted in FIG. 4 and FIG. 5, the cooling plate 54 is displaceably supported in a direction of facing the heat transfer plate 26 (in this case, the lateral width direction of the housing 24).

The cooling plate 54 is formed of a hollow body. As depicted in FIG. 4, an inner space 64 of the cooling plate 54 is partitioned in the height direction of the housing 24 by a partitioning wall 66 extending in the longitudinal direction of the housing 24. By way of example, a lower part of the inner space 64 serves as a forward path 64A through which the coolant 65 flows from an external coolant supply apparatus, which will be described further below, and an upper part of the inner space 64 serves as a return path 64B through which the coolant 65 flows from the forward path 64A to the coolant supply apparatus.

The spring 56 is made of stainless steel, for example, and is interposed between the slider 44 and the cooling plate 54 (more specifically, between the body part 48 of the slider 44 and the cooling plate 54). By way of example, the spring 56 is a wave-shaped spring formed by processing a flat plate into a wavy shape. The spring 56 presses the cooling plate 54 toward the heat transfer plate 26 with respect to the body part 48 of the slider 44.

The spring 56 is formed so as to have a long length and, as with the cooling plate 54, is disposed, with the longitudinal direction of the housing 24 taken as a length direction. With this, the cooling plate 54 is pressed by the spring 56 over the length direction toward the heat transfer plate 26. The cooling plate 54 is in contact with the heat transfer plate 26 as being superposed thereon over the length direction of the heat transfer plate 26.

The cooling plate 54 is provided with an entrance part 68 connected to the forward path 64A and an exit part 70 connected to the return path 64B. To the entrance part 68 and the exit part 70, paired hoses 72 and 74 are connected, respectively.

On the other hand, as depicted in FIG. 1, the lower frame 11 provided to the above-described rack 10 is provided with a feed pipe 76 and a drain pipe 78 are provided. To the feed pipe 76 and the drain pipe 78, a coolant supply apparatus 80 is connected, which is an example of an external coolant supply part. In one pole 14 provided on the rear surface side of the rack 10, paired flow paths 82 and 84 are formed. The feed pipe 76 and the drain pipe 78 are connected via the flow paths 82 and 84 and the hoses 72 and 74 to the entrance part 68 and the exit part 70 of the above-described cooling plate 54 (refer to FIG. 4), respectively.

In the electronic apparatus S including the cooling unit 58, the heat producing body 30 (refer to FIG. 4) of the electronic device 20 is cooled as follows. That is, when the coolant is sent out from the coolant supply apparatus 80 depicted in FIG. 1, the coolant flows via the feed pipe 76, the flow path 82, and the hose 72 into the forward path 64A formed inside the cooling plate 54 depicted in FIG. 4. The coolant flowing through the forward path 64A and then through the return path 64B is returned from the hose 74 via the flow path 84 and the drain pipe 78 depicted in FIG. 1 to the coolant supply apparatus 80. In this manner, the coolant is circulated between the cooling plate 54 and the coolant supply apparatus 80.

Here, as depicted in FIG. 4, the cooling plate 54 is pressed by the spring 56 toward the heat transfer plate 26 to be brought into contact with the heat transfer plate 26, thereby cooling the heat transfer plate 26. Also, the heat producing part 34 and the heat transfer plate 26 are connected via the heat pipes 28, and heat produced at the heat producing body 30 is transferred via the heat dissipating plate 32 and the heat pipes 28 to the heat transfer plate 26. Then, with the heat produced at the heat producing body 30 conveyed via the heat pipes 28 to the heat transfer plate 26, the heat producing body 30 is cooled.

Next, the operation and effect of the present embodiment are described.

As has been described in detail above, according to the electronic apparatus S of the present embodiment, the cooling plate 54 where the coolant is circulated to and from the coolant supply apparatus 80 is disposed outside the housing 24. Also, as a cooling part accommodated in the housing 24 for cooling the heat producing body 30, the heat pipes 28 are used, which allow size reduction more easily than a general cooling mechanism where a coolant is circulated (a hefty mechanism with components such as pipes and couplers). Therefore, the space inside the housing 24 is saved. With this, for example, high-density implementation of the circuit board 22 is possible.

Furthermore, as described above, the heat pipes 28 filled with the hydraulic fluid 42 in a hermetically sealed state are used as a cooling part accommodated in the housing 24, and the cooling plate 54 where the coolant is circulated is disposed outside the housing 24. Therefore, leakage of the coolant inside the housing 24 is reduced. With this, a tray for leakage fluid collection may not be disposed inside the housing 24, thereby saving the space inside the housing 24.

Still further, as depicted in FIG. 4, the heat transfer plate 26 is provided from the front surface 24B side to the rear surface 24C side of the side surface 24A of the housing 24, and the cooling plate 54 formed so as to have a long length is brought into contact with the heat transfer plate 26 over the length direction of the heat transfer plate 26. Therefore, heat transfer efficiency between the heat transfer plate 26 and the cooling plate 54 is enhanced. Therefore, the heat at the heat producing body 30 is efficiently transferred to the cooling plate 54. With this, cooling efficiency of the heat producing body 30 is improved.

Still further, the cooling unit 58 has the spring 56, and the cooling plate 54 is pressed by the spring 56 toward the heat transfer plate 26. Therefore, the heat transfer plate 26 and the cooling plate 54 are brought into closer contact with each other. In particular, the spring 56 is formed so as to have a long length, is disposed, with the longitudinal direction of the housing 24 taken as a length direction, and presses the cooling plate 54 toward the heat transfer plate 26 over the length direction. Therefore, the cooling plate 54 is brought into close contact with the heat transfer plate 26 over the length direction. With this, heat transfer efficiency between the heat transfer plate 26 and the cooling plate 54 is more enhanced.

Still further, since the plurality of heat pipes 28 are connected to one heat transfer plate 26, heat transfer efficiency between the heat producing body 30 and the heat transfer plate 26 is also enhanced.

Still further, the slider 44 provided on the side part of the electronic device 20 has not only the function of slidably supporting the electronic device 20 to the rack 10 but also the function as a bracket for mounting the cooling plate 54 on the side surface 24A of the housing 24. Therefore, an increase in the number of members is reduced for cost reduction.

Still further, the cooling unit 58 having the sliders 44 and the cooling plate 54 are provided to the side surface 24A of the housing 24, as an example of disposing outside the housing 24. Therefore, an increase in the dimension of the electronic device 20 including the cooling plate 54 in the height direction is reduced.

Still further, the sliders 44 and the cooling plate 54 are each formed so as to have a long length, and are disposed, with the longitudinal direction of the housing 24 taken as a length direction. The both ends of each slider 44 in the length direction are fixed to the side surface 24A of the housing 24, and the both ends of the cooling plate 54 in the length direction are fixed to the both ends of the slider 44 in the length direction. Therefore, the sidewall part 36 of the electronic device 20 is reinforced by the cooling plate 54 made of metal with high stiffness.

Meanwhile, for example, when the cooling unit 58 is provided to the rack 10, positional accuracy of each electronic device 20 with respect to the rack 10 may influence the degree of close contact between the cooling plate 54 and the heat transfer plate 26. Regarding this point, according to the present embodiment, since the cooling unit 58 is integrally provided with each electronic device 20, the influence of positional accuracy of each electronic device 20 with respect to the rack 10 over the degree of close contact between the cooling plate 54 and the heat transfer plate 26 is reduced. With this, the degree of close contact between the cooling plate 54 and the heat transfer plate 26 is ensured.

Next, modification examples of the present embodiment are described.

In the above-described embodiment, as depicted in FIG. 8, the inner space 64 of the cooling plate 54 may be partitioned by the partitioning wall 66 in a direction of facing the heat transfer plate 26 and the cooling plate 54 (in this case, in the lateral width direction of the housing 24). A side of the inner space 64 near the heat transfer plate 26 with reference to the partitioning wall 66 may be taken as the forward path 64A, and a side of the inner space 64 opposite to the heat transfer plate 26 with reference to the partitioning wall 66 may be taken as the return path 64B. With this structure, compared with the case in which the forward path 64A and the return path 64B are aligned in the height direction of the housing 24, a contact area between a portion of the cooling plate 54 on the forward path 64A side and the heat transfer plate 26 is enhanced. Therefore, heat transfer efficiency between the heat transfer plate 26 and the cooling plate 54 is further increased.

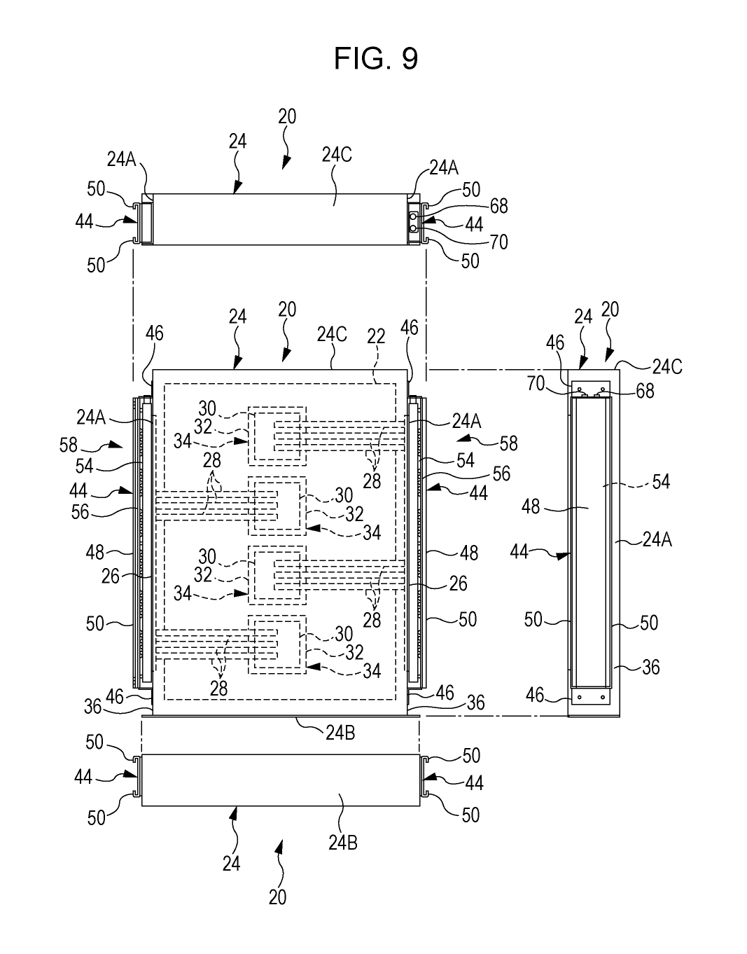

Also, in the above-described embodiment, the cooling unit 58 is provided only one of the paired side surfaces 24A of the housing 24. Alternatively, as depicted in FIG. 9, the cooling unit 58 may be provided on both of the paired side surfaces 24A of the housing 24. Furthermore, the heat transfer plate 26 and the cooling unit 58 may be provided on an outer surface other than the side surfaces 24A of the housing 24, and a plurality of combinations of the heat transfer plate 26 and the cooling unit 58 may be provided to the electronic apparatus S.

Still further, as depicted in FIG. 9, a plurality of heat producing bodies 30 may be mounted on the circuit board 22. Each of the heat producing bodies 30 may be connected via the plurality of heat pipes 28 to the heat transfer plate 26.

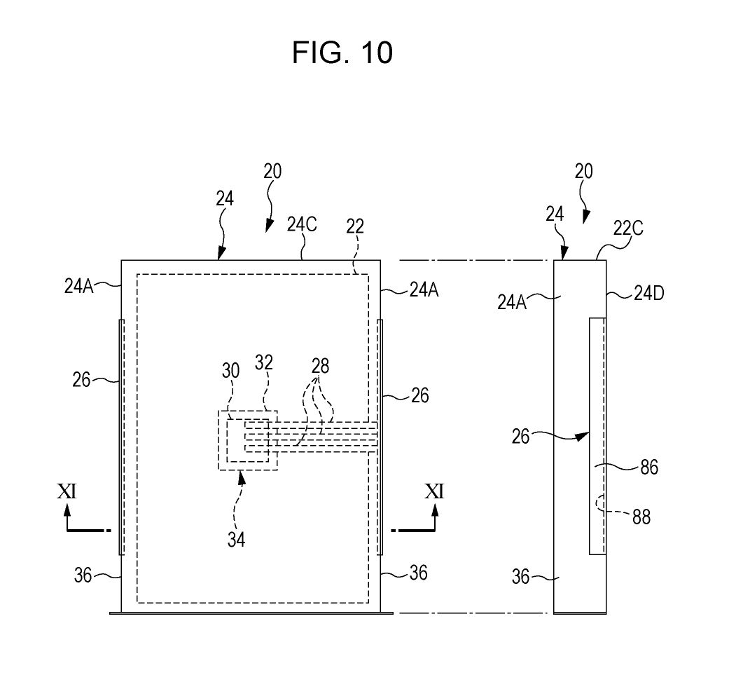

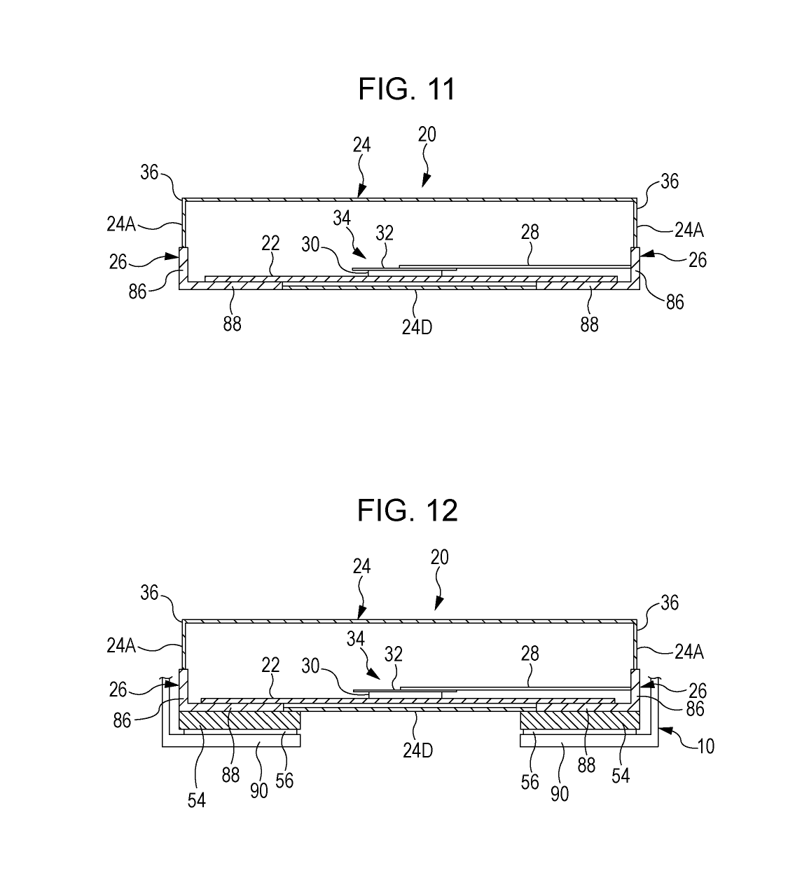

Still further, the heat transfer plate 26, the cooling plate 54, and the spring 56 described above may be configured as follows. That is, in a modification example depicted in FIG. 10 to FIG. 12, the heat transfer plate 26 has a side part 86 and a bottom part 88 exposed to the side surface 24A and the bottom surface 24D, respectively, of the outer surfaces of the housing 24. Also, as depicted in FIG. 12, the cooling plate 54 is mounted on the rack 10 as an example of disposing outside the housing 24. More specifically, the cooling plate 54 is provided to a facing part 90 of the rack 10 facing the bottom surface 24D.

Still further, the spring 56 is interposed between the cooling plate 54 and the facing part 90, and presses the cooling plate 54 toward the heat transfer plate 26 with respect to the facing part 90. An end of each heat pipe 28 opposite to the heat producing part 34 is connected to the side part 86 of the heat transfer plate 26.

With the above-described structure, in addition to the pressure of the spring 56, the self weight of the electronic device 20 brings the heat transfer plate 26 and the cooling plate 54 into close contact with each other. Also, since the cooling plate 54 is mounted on the rack 10, the electronic device 20 is slidable with respect to the rack 10, as hoses being connected to the cooling plate 54.

In the modification example depicted in FIG. 10 to FIG. 12, the side part 86 may be omitted from the heat transfer plate 26. Also in this case, the end of the heat pipe 28 opposite to the heat producing part 34 may be connected to the bottom part 88 of the heat transfer plate 26.

Also, while the heat producing part 34 has the heat producing body 30 and the heat dissipating plate 32 in the above-described embodiment, the heat dissipating plate 32 may be omitted from the heat producing part 34. Also in this case, one end of the heat pipe 28 may be directly connected to the heat producing body 30.

Furthermore, while the spring 56, as an example of a pressing member, is interposed between the slider 44 and the cooling plate 54 as depicted in FIG. 4, a pressing member other than the spring 56 (for example, elastic rubber) may be interposed between the slider 44 and the cooling plate 54.

Still further, while the electronic apparatus S includes the plate-shaped heat transfer plate 26 and cooling plate 54 as examples of the heat transfer member and the cooling member, the electronic apparatus S may include a heat transfer member and a cooling member each formed in a shape other than a plate shape, in place of the heat transfer plate 26 and the cooling plate 54.

Among the plurality of modification examples described above, those combinable may be combined as appropriate.

While an embodiment of the technology disclosed herein has been described in the foregoing, the technology disclosed herein is not restricted by the above description, and it goes without saying that the technology disclosed herein may be implemented as being variously modified within a range not deviating from the gist of the technology disclosed herein.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An electronic apparatus comprising:
an electronic device including
a housing that accommodates a heat producing part,
a heat transfer member configured to be exposed to an outer surface of the housing, and
a heat pipe accommodated in the housing and configured to connect the heat producing part and the heat transfer member; and
a cooling member, in contact with the heat transfer member, that is disposed on an outside of the housing, the cooling member in which a coolant circulating to and from an external coolant supply part.

2. The electronic apparatus according to claim 1, further comprising:
a rack where the electronic device is mounted.

3. The electronic apparatus according to claim 1,
wherein the cooling member is mounted on an outer surface of the housing as the outside of the housing.

4. The electronic apparatus according to claim 3, further comprising:
a rack where the electronic device is mounted,
wherein the electronic device is provided with a slider,
the rack is provided with a guide part that slidably supports the slider, and
the cooling member is supported by the slider.

5. The electronic apparatus according to claim 4,
wherein the heat transfer member is exposed to a side surface of the outer surface of the housing, and
the slider is provided to the side surface of the housing.

6. The electronic apparatus according to claim 5,
wherein the cooling member is made of metal,
the slider and the cooling member are each formed so as to have a long length and disposed, with a longitudinal direction of the housing taken as a longitudinal direction,
the slider has both ends in the length direction fixed to the side surface of the housing, and
the cooling member has both ends in the length direction fixed to the both ends of the slider in the length direction.

7. The electronic apparatus according to claim 1,
wherein the heat transfer member is formed so as to have a long length, and
the cooling member is brought into contact with the heat transfer member over a length direction of the heat transfer member.

8. The electronic apparatus according to claim 7,
wherein the heat transfer member is provided on a front surface side to a rear surface side of the housing.

9. The electronic apparatus according to claim 1,
wherein the heat transfer member is a heat transfer plate provided along the side surface of the housing, and
the cooling member is a cooling plate to be superposed on the heat transfer plate.

10. The electronic apparatus according to claim 1,
wherein the cooling member is a hollow body,
the cooling member has an inner space partitioned by a partitioning wall in a direction of facing the heat transfer member and the cooling member,
a side of the inner space near the heat transfer member with reference to the partitioning wall is taken as a forward path through which the coolant flows from the external coolant supply part, and
a side of the inner space opposite to the heat transfer member with reference to the partitioning wall is taken as a return path through which the coolant flows from the forward path to the external coolant supply part.

11. The electronic apparatus according to claim 1, further comprising:
a pressing member that presses the cooling member toward the heat transfer member.

12. The electronic apparatus according to claim 11,
wherein the pressing member presses the cooling member toward the heat transfer member over the length direction of the cooling member.

13. The electronic apparatus according to claim 11, further comprising a rack where the electronic device is mounted,
wherein the electronic device is provided with a slider,
the rack is provided with a guide part that slidably supports the slider,
the cooling member is supported by the slider, and
the pressing member is a spring interposed between the slider and the cooling member.

14. The electronic apparatus according to claim 13,
wherein the slider has a support part that displaceably supports the cooling member in a direction of facing the heat transfer member.

15. The electronic apparatus according to claim 1, further comprising:
a plurality of combinations of the heat transfer member and the cooling member are provided.

16. The electronic apparatus according to claim 1,
wherein a plurality of said heat pipes are connected to one said heat transfer member.

17. The electronic apparatus according to claim 1, further comprising:
a rack where the electronic device is mounted,
wherein the cooling member is mounted on the rack as the outside of the housing.

18. The electronic apparatus according to claim 17,
wherein the heat transfer member is exposed to at least a bottom surface as the outer surface of the housing, and
the cooling member is provided to a part of the rack that faces the bottom surface.

19. The electronic apparatus according to claim 18,
wherein the heat transfer member has a side part exposed to a side surface of the outer surface of the housing and a bottom part exposed to the bottom surface as the outer surface of the housing.

20. The electronic apparatus according to claim 19,
wherein the heat pipe is connected to the side part of the heat transfer member.
